(19) United States
(12) Patent Application Publication
(10) Pub. No.: US 2026/0029430 A1
(43) Pub. Date: Jan. 29, 2026

(54) APPARATUSES AND METHODS FOR PROBE TIP ALIGNMENT

(71) Applicant: Micron Technology, Inc., Boise, ID (US)

(72) Inventors: Yosuke Irie, Boise, ID (US); Akiyoshi Seko, Hiroshima (JP); Kazuki Hisakane, Hiroshima (JP)

(73) Assignee: Micron Technology, Inc., Boise, ID (US)

(21) Appl. No.: 19/261,049

(22) Filed: Jul. 7, 2025

Related U.S. Application Data
(60) Provisional application No. 63/676,497, filed on Jul. 29, 2024.

(51) Int. Cl. G01R 1/067; G01R 1/073

(52) U.S. Cl. CPC G01R 1/06794; G01R 1/07342

(57) ABSTRACT

A misalignment detector may be included on a test module to determine if one or more probe tips of a probe card are misaligned from the probe pads on the test module. In some examples, the misalignment detector may include two or more detection rails. In some examples, one or more probe pads may be coupled to one of the detection rails. In some examples, the misalignment detector may include one or more test element groups. In some examples, the misalignment detector may include one or more shorting lines. In some examples, portions of the misalignment detector may be included in different conductive layers.

### CROSS REFERENCE TO RELATED APPLICATION(S)

This application claims the benefit under 35 U.S.C. § 119 of the earlier filing date of U.S. Provisional Application Ser. No. 63/676,497 filed Jul. 29, 2024 the entire contents of which is hereby incorporated by reference in its entirety for any purpose.

### BACKGROUND

Semiconductor devices, such as memory devices, are fabricated on wafers. Tens to hundreds of die (which may each be a separate semiconductor device) may be on a single wafer. In some applications, the die may be quality tested while still on the wafer. FIG. 1 is a block diagram of a semiconductor testing system. The components are not drawn to scale. A wafer 102 including many die 110 may have one or more test modules 104. Although FIG. 1 shows sixteen die 110, it is understood that the wafer 102 may have any number of die 110, and the wafer 104 may include dozens or hundreds of die 110. The test modules 104 may be associated with one or more die 110 on the wafer 102. Although test modules 104 are shown in FIG. 1 as being at the edges of die 110, the test modules 104 may be in other locations on the wafer 102 relative to the die 110. Further, the number of test modules 104 may be different in other cases (e.g., one or more per die 110). The test module 104 may include one or more probe pads. A probe card 106 including a set of probe tips (also referred to as pins) may be placed on the test module 104. The probe tips may be placed on the probe pads on the test module 104. Although only one probe card 106 is shown in FIG. 1, multiple probe cards 106 could be used in other cases. The probe card 106 may be coupled to a tester 108. The tester 108 may include a computing device. The tester 108 sends electrical signals to the probe tips of the probe card 106. The electrical signals are provided to the test module 104. The electrical signals may include data, commands, and/or other signals. The probe tips may receive signals from the probe pads of the test module 104 and provide the signals to the tester 108. The electrical signals may include data, status signals, and/or other signals. The tester 108 may analyze the signals from the test module 104 to determine whether components located on the wafer 102 are operating properly. After testing, the wafer 102 may be cut into the individual die 110.

### BRIEF DESCRIPTION OF THE DRAWINGS

FIG. 1 is a block diagram of a semiconductor testing system.

FIGS. 2A and 2B illustrate two types of probe cards

FIG. 3A illustrates placement of probe tips on probe pads.

FIG. 3B illustrates a probe tip misalignment detector in accordance with at least one embodiment of the present disclosure.

FIG. 4 illustrates a probe tip misalignment detector in accordance with at least one embodiment of the present disclosure.

FIG. 5 illustrates a probe tip misalignment detector in accordance with at least one embodiment of the present disclosure.

FIG. 6A illustrates the probe tip misalignment detector shown in FIG. 5.

FIG. 6B illustrates the probe tip misalignment detector shown in FIG. 5.

FIG. 7A illustrates the probe tip misalignment detector shown in FIG. 5.

FIG. 7B illustrates the probe tip misalignment detector shown in FIG. 5.

FIG. 8 illustrates a probe tip misalignment detector in accordance with at least one embodiment of the present disclosure.

FIG. 9 illustrates the probe tip misalignment detector shown in FIG. 8.

FIG. 10 illustrates a probe tip misalignment detector in accordance with at least one embodiment of the present disclosure.

FIG. 11A illustrates the probe tip misalignment detector shown in FIG. 10.

FIG. 11B illustrates the probe tip misalignment detector shown in FIG. 10.

FIG. 12A illustrates the probe tip misalignment detector shown in FIG. 10.

FIG. 12B illustrates the probe tip misalignment detector shown in FIG. 10.

FIG. 13A illustrates the probe tip misalignment detector shown in FIG. 10.

FIG. 13B illustrates the probe tip misalignment detector shown in FIG. 10.

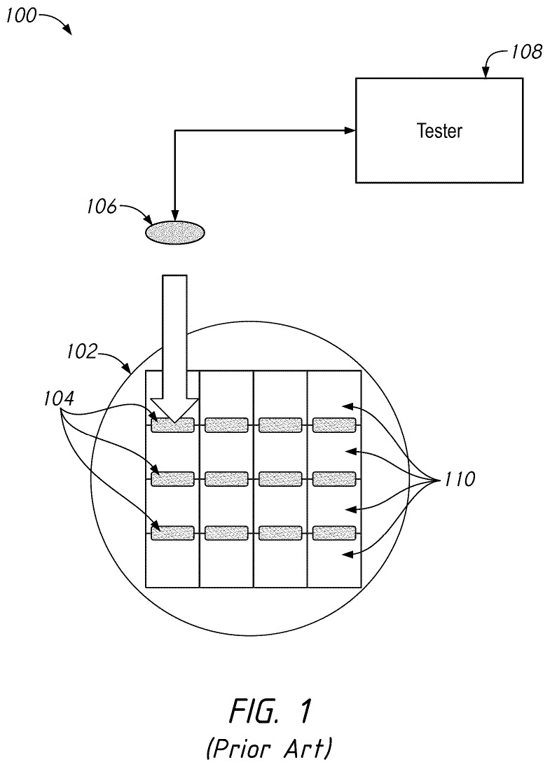

### DETAILED DESCRIPTION

Certain details are set forth below to provide a sufficient understanding of embodiments of the disclosure. However, it will be clear to one having skill in the art that embodiments of the disclosure may be practiced without these particular details. Moreover, the particular embodiments of the present disclosure described herein are provided by way of example and should not be used to limit the scope of the disclosure to these particular embodiments.

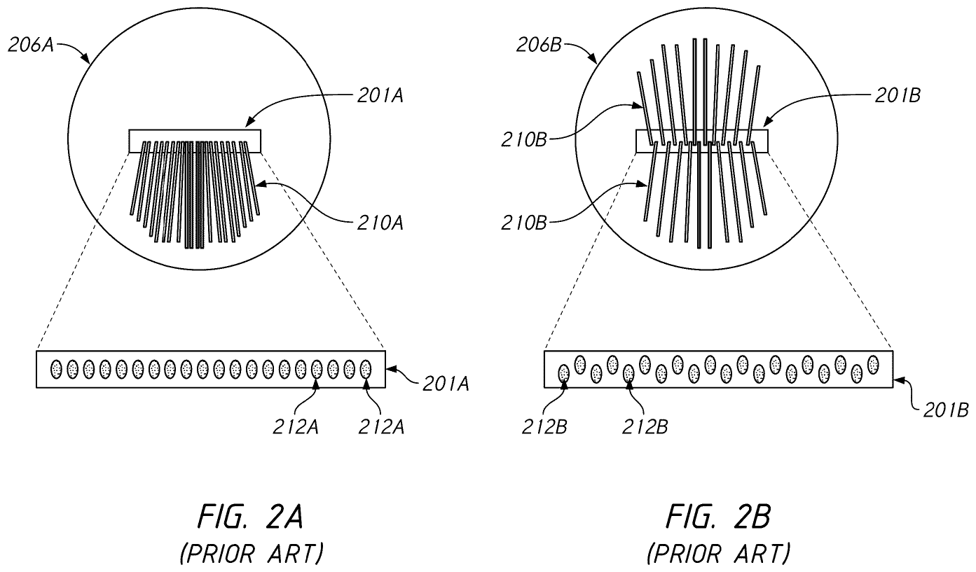

FIGS. 2A and 2B illustrate two types of probe cards. Probe cards 206A and 206B may be used as probe card 106 in some embodiments. In FIG. 2A, probe card 206A includes multiple probe needles 210A. The probe needles 210A may be coupled to wires to connect to a tester, such as tester 108. As shown in the enlarged box 201A, the tips 212A of needles 210A are aligned in a straight line. This is sometimes referred to as a single sided card. In contrast, in FIG. 2B, probe card 206B has probe needles 210B which have tips 212B (e.g., probe tips) that are in are in a staggered formation as shown in box 201B. By staggered, it means two parallel lines of probe tips that are interleaved with an offset between the two lines. This is sometimes referred to as a double sided card. Which probe card 206A, 206B is used may depend, at least in part, on the size of the probe pads of the test module. For example, in some applications, double sided cards may have more consistent needle pressure between odd and even pins than single sided cards. However, double sided card may be more difficult to obtain tip alignment between odd pins and even pins. Single sided cards may be easier to obtain tip alignment, which may be due at least in part to the wear out direction being in the same between even and odd pins. However, in some cases, it may be more difficult for single sided cards to provide consistent needle pressure between odd pins and even pins. Accordingly, in some applications, double sided cards may be preferred for larger probe pads and single sided cards may be preferred for smaller probe pads.

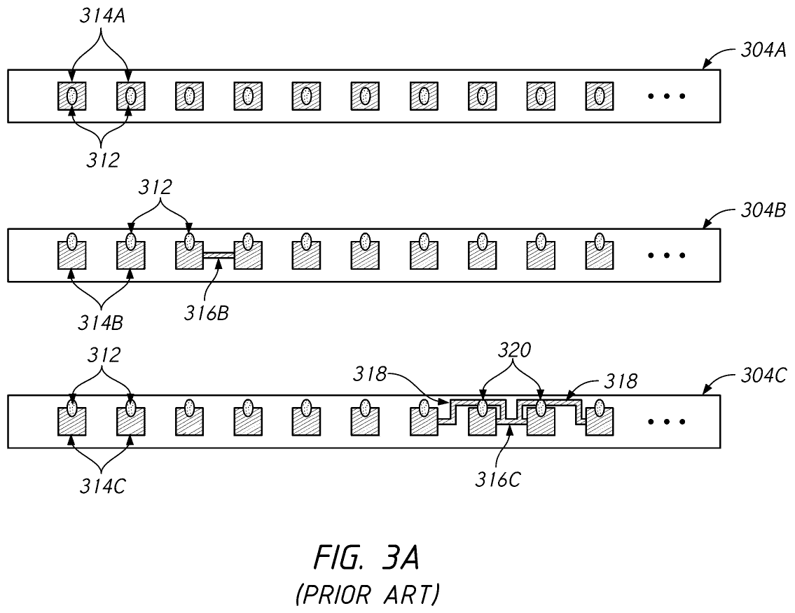

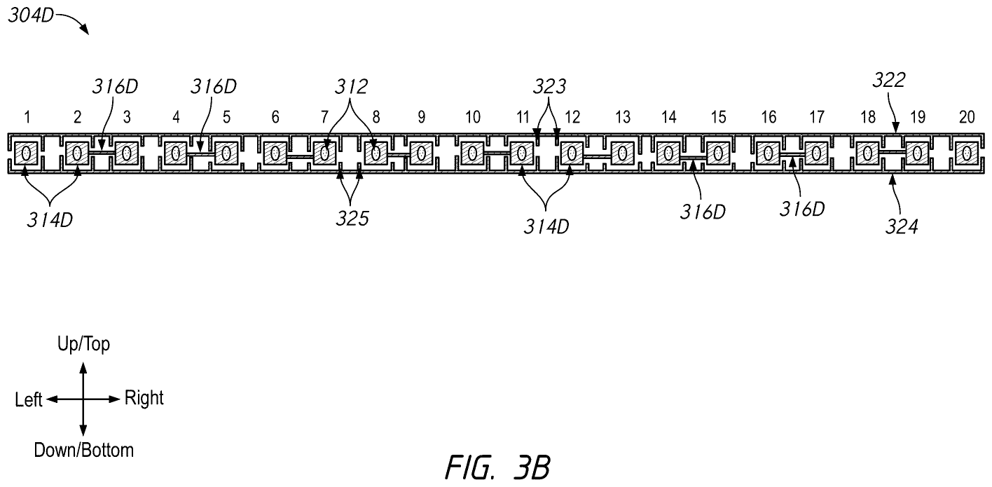

FIG. 3A illustrates placement of probe tips on probe pads. Test module 304A includes a number of probe pads 314A. Probe tips 312 are placed on or near the center of probe pads 314A. In contrast, on test module 304A and test module 304C, the probe tips 312 are offset from the center of probe pads 314B and 314C and are at least partially off the probe pads 314B and 314C.

When the probe tips 312 are not completely on the probe pads 314B and 314C, the probe tips 312 may register higher resistance and/or lower signal strength from the probe pads 314B and 314C. If the probe pads 314B, 314C are connected in a test element group (TEG) 316B, 316C and/or include conductive routing 318C between probe pads 314B, 314C and/or TEG, the offset probe tips may create shorts 320. The high resistance, lower signal strength, and/or shorts may create faulty testing results. This may result in a tester being able to run tests and/or making incorrect determinations as to whether components on the wafer are defective or not.

In some applications, it may be difficult to determine that the probe tips are not aligned with the probe pads. Even if the tester can determine the probe tips are misaligned based on electrical signals (e.g., high resistance, noise, etc.), it cannot determine the direction of the misalignment. Further, the probe tips and probe pads are small and often made of the same material as one another, so it can be difficult for a user to visually determine the direction of misalignment. It may take several tries repositioning the probe card and/or wafer to achieve alignment between the probe tips and probe pads. Accordingly, improved techniques for determining alignment between probe tips and probe pads may be desirable.

This application describes examples of probe tip misalignment detectors. The probe tip misalignment detectors may be used to determine whether probe tips are aligned on probe pads. In some embodiments, the probe tip misalignment detectors may be able to determine one or more directions of misalignment. This may allow users to determine a direction in which the probe card and/or wafer should be moved to improve alignment.

In the examples shown, test modules include twenty (20) probe pads and the probe card includes twenty (20) probe tips. However, this is provided merely for illustration, and test modules may include any number of probe pads and the probe card may include any number of probe tips. Further, as used herein, spatial relational terms such as “left,” “right,” “upper,” and “lower” and variations thereof are used for convenience to refer to directions with reference to the figure pages as viewed by a reader. They do not necessarily refer to the actual physical orientations of probe tips and probe pads to one another in a testing system. For example, the probe card may be coupled to the test module from above, below, or on a side of a wafer depending on the configuration of the testing system used. Accordingly, the use of such terms should not be interpreted as limiting relative arrangements of the test module, probe card, and other features.

FIG. 3B illustrates a probe tip misalignment detector in accordance with at least one embodiment of the present disclosure. Test module 304D includes a number of probe pads 314D. Some of the probe pads 314D (e.g., probe pads 4 and 5) are connected as test element groups 316D. The test module 304D further includes additional conductive traces to implement the misalignment detector. The conductive traces may be used as detection rails 322 and 324. Detection rail 322 extends along the “top” of the probe pads 314D and detection rail 324 extends along the “bottom” of the probe pads 314D.

The detection rails 322 and 324 may allow for a tester (e.g., tester 108) to determine whether the probe tips 312 are misaligned with the probe pads 314. Prior to testing, the tester may ground one or more probe tips 312, apply a voltage to one or more probe tips 312, and float the remaining probe tips 312. The tester may then measure a current between the probe tip 312 with the applied voltage and the probe tip 312 that has been grounded to detect misalignments. The tester may ground and apply voltages to probe tips 312 associated with a pair probe pads 314 that are not connected by a TEG 316. For example, probe tips 312 associated with probe pads 1 and 2 or probe pads 3 and 4.

For example, the tester may ground the probe tip 312 expected to be on probe pad 1 and apply a voltage to the probe tip 312 expected to be on probe pad 2 (as is apparent to one having skill in the art, alternatively, a voltage may be applied to the probe tip 312 expected to be on probe pad 1 and ground the probe tip 312 expected to be on probe pad 2). If a current is detected, it may indicate that the probe tips 312 are misaligned because the probe tips 312 have created contacts (not shown in FIG. 3B) with the detection rail 322 or 324. However, the electrical signals provided to the tester may be the same whether the probe tips 312 are misaligned upward (e.g., off the tops of the probe pads 314D) or downwards (e.g., off the bottoms of the probe pads 314D).

The detection rails 322 may include extended portions 323 that extend along at least a portion of the left and right sides of the probe pads 314D, and the detection rails 324 may include extended portions 325 that extend along at least apportion of the left and right side of the probe pads 314D. If the probe tips 312 are misaligned to the left or right of the probe pads 314D, the probe tips 312 may form contacts (not shown) with the extended portions 323 and/or extend portions 325. However, again, the electrical signals provided to the tester may be the same whether the probe tips 312 are misaligned to the left or right. Further, these signals may be the same as when the probe tips 312 are misaligned from the top or the bottom.

The TEG 316D may be utilized to determine if some probe tips 312 are missing, failing, and/or not in contact with the probe pad 304D. For example, the probe tip 312 associated with probe pad 2 may be grounded and a probe tip 312 associated with probe pad 3 may have a voltage applied. If a current is detected, it means both probe tips 312 are in contact with the probe pads 314D. If no current is detected, it means that one (or both) of the two probe tips 312 are in contact with the probe pads 314D.

While the misalignment detector illustrated in FIG. 3B may require minor additional conductive traces, the misalignment detector may not provide sufficient information to the tester as the adjustments needed (to either the probe tips and/or the test module) to improve alignment between the probe tips 312 and the probe pads 314D. In some applications, additional information regarding the relative orientation of the probe tips 312 to the probe pads 314D may be desired.

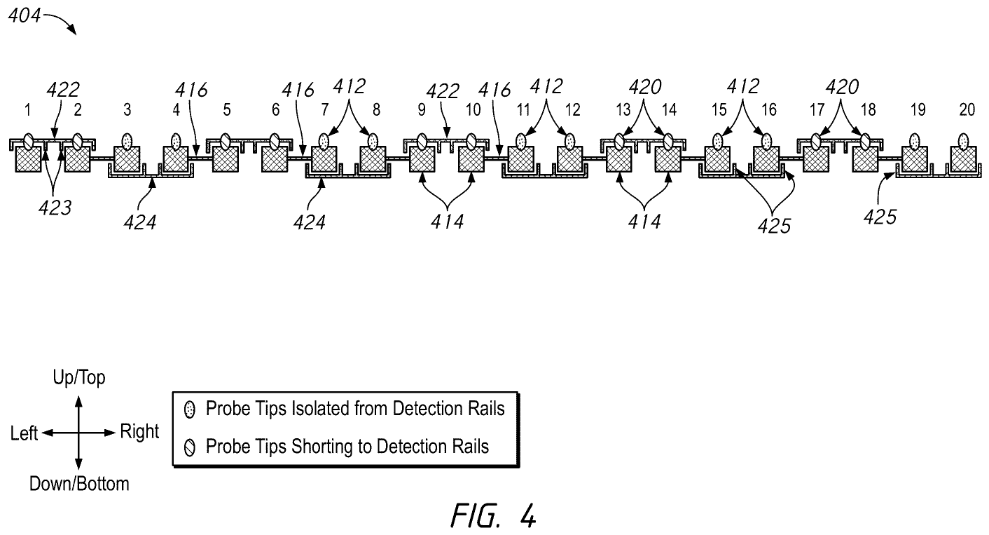

FIG. 4 illustrates a probe tip misalignment detector in accordance with at least one embodiment of the present disclosure. Test module 404 includes a number of probe pads 414. Some of the probe pads 414 (e.g., probe pads 4 and 5) are connected as test element groups 416. The test module 404 further includes additional conductive traces to implement the misalignment detector. The conductive traces may be used as detection rails 422 and 424. Detection rails 422 extend along the “top” of alternating pairs of two adjacent probe pads 414. Similarly, detection rails 424 extend along the “bottom” of alternating pairs of two adjacent probe pads 414. In the example shown in FIG. 4, probe pads 1-2, 5-6, 9-10, 13-14, and 17-18 have detection rails 422 along the top, and probe pads 3-4, 7-8, 11-12, 15-16, and 19-20 have detection rails 424 along the bottom. However, other arrangements may be used without departing from the scope of the present embodiment (e.g., probe pads 1-2, 5-6, 9-10, 13-14, and 17-18 have detection rails 424 along the bottom, and probe pads 3-4, 7-8, 11-12, 15-16, and 19-20 have detection rails 422 along the top).

The detection rails 422 and 424 may allow for a tester (e.g., tester 108) to determine whether the probe tips 412 are misaligned in the top or bottom direction. Prior to testing, the tester may ground one or more probe tips 412, apply a voltage to one or more probe tips 412, and float the remaining probe tips 412. The tester may then measure a current between the probe tip 412 with the applied voltage and the probe tip 412 that has been grounded to detect misalignments. The tester may ground and apply voltages to probe tips 412 associated with a pair probe pads 414 associated with a same detection rail. For example, a pair of probe pads 414 associated with a detection rail 422 (e.g., probe pads 5-6) and/or a pair of probe pads associated with a detection rail 424 (e.g., probe pads 7-8).

For example, the tester may ground the probe tip 412 expected to be on probe pad 1 and apply a voltage to the probe tip 412 expected to be on probe pad 2 (as is apparent to one having skill in the art, alternatively, a voltage may be applied to the probe tip 412 expected to be on probe pad 1 and ground the probe tip 412 expected to be on probe pad 2). If a current is detected, it may indicate that the probe tips 412 are misaligned and are off the top of the probe pads 414 as shown in the example in FIG. 4 because the probe tips 412 have created contacts 420 with the detection rail 422. The test may be repeated (or performed simultaneously) for the other pairs associated with detection rails 422.

Similarly, the tester may ground the probe tip 412 expected to be on probe pad 3 and apply a voltage to the probe tip 412 expected to be on probe pad 4. If a current is detected, it may indicate that the probe tips 412 are misaligned and are offset from the bottom of the probe pads 414 (not shown in FIG. 4) because the probe tips 412 have created contacts 420 with the detection rail 424. The test may be repeated (or performed simultaneously) for the other pairs associated with detection rails 424. Thus, if the tester detects current through detection rails 422, it can determine the probe tips 412 should be moved down to improve alignment (or the test module 404 should be moved up), and if the tester detects current through detection rails 424, it can determine the probe tips 412 should be moved up to improve alignment (or the test module 404 should be moved down).

Pairs of probe tips 412 associated with probe pads 414 may be tested sequentially and in some cases, some pairs may be tested simultaneously. The TEG 416 may be utilized to determine if some probe tips 412 are missing, failing, and/or not in contact with the probe pad 404. For example, the probe tip 412 associated with probe pad 2 may be grounded and a probe tip 412 associated with probe pad 3 may have a voltage applied. If a current is detected, it means both probe tips 412 are in contact with the probe pads 414. However, if no current is detected, it means that one (or both) of the two probe tips 412 are in contact with the probe pads 414.

The detection rails 422 may include extended portions 423 that extend along at least a portion of the left and right sides of the probe pads 414, and the detection rails 424 may include extended portions 425 that extend along at least apportion of the left and right side of the probe pads 414. If the probe tips 412 are misaligned to the left or right of the probe pads 414, the probe tips 412 may form contacts (not shown) with the extended portions 423 and/or extend portions 425. However, while the tester may be able to determine the probe tips 412 are misaligned to a side, the tester may not be able to determine specifically that the probe tips 412 are misaligned to the left or right.

The embodiment of the misalignment detector shown in FIG. 4 does not require the addition of a significant amount of detection rails or other components, and it allows for determining if the probe tips 412 should be moved up or down (relative to the probe pads 414 as shown on the page). However, the misalignment detector shown in FIG. 4 may not compatible with a double sided card where the probe tips 412 are in a staggered arrangement as shown in FIG. 2B.

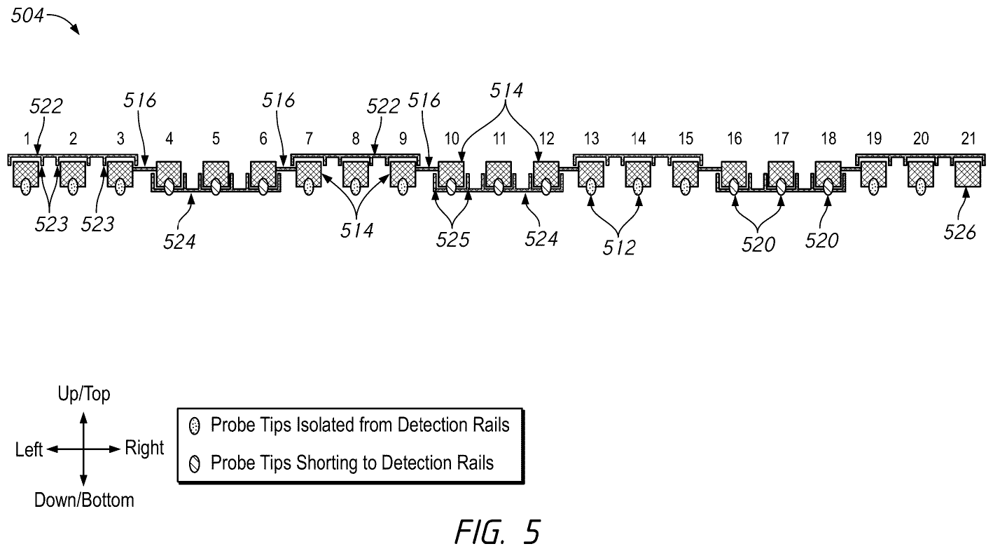

FIG. 5 illustrates a probe tip misalignment detector in accordance with at least one embodiment of the present disclosure. Test module 504 includes a number of probe pads 514. Some of the probe pads 514 (e.g., probe pads 6 and 7) are connected as test element groups 516. The test module 504 further includes detection rails 522 and 524 to act as a misalignment detector. Detection rails 522 extend along the “top” of alternating trios of three consecutive probe pads 514. Similarly, detection rails 524 extend along the “bottom” of alternating trios of three consecutive probe pads 514. In the example shown in FIG. 5, probe pads 1-3, 7-9, 13-15, and 19-21 have detection rails 522 along the top, and probe pads 4-6, 10-12, and 16-18 have detection rails 524 along the bottom. However, other arrangements may be used without departing from the scope of the present embodiment (e.g., probe pads 1-3, 7-9, 13-15, and 19-21 have detection rails 524 along the bottom, and probe pads 4-6, 10-12, and 16-18 have detection rails 522 along the top).

The misalignment detector shown in FIG. 5 includes detection rails 522 and 524 that are associated with trios of probe pads 514 instead of pairs of probe pads as shown in FIG. 4. The misalignment detector further includes an additional pad 526 (compared to the test module 404 shown in FIG. 4) such that the number of probe pads 514 is a multiple of three (21 probe pads in the example shown in FIG. 5). However, if a test module already has a number of probe pads that is a multiple of three, additional probe pads 526 may be omitted. The additional probe pads 526 may be used for alignment and testing (e.g., assigned a probe tip and used to run tests on the wafer) or may be used only for alignment. For example, double-sided cards may have different configurations (e.g., even pins on upper row and odd pins on lower row for one configuration and vice versa for another configuration). The additional pad 526 may be used in some configurations, but not others. Further, while the additional probe pad 526 is shown as after probe pad 20 as probe pad 21 in FIG. 5, the additional probe pad 526 may be included before probe pad 1 as probe pad −1 or 0.

The detection rails 522 and 524 may allow for a tester (e.g., tester 108) to determine whether the probe tips 512 are misaligned in the top or bottom direction. Prior to testing, the tester may ground one or more probe tips 512, apply a voltage to one or more probe tips 512, and float the remaining probe tips 512. The tester may then measure a current between the probe tip 512 with the applied voltage and the probe tip 512 that has been grounded to detect misalignments. The tester may ground and apply voltages to probe tips 512 associated with a trio of probe pads 514 associated with a same detection rail. For example, a trio of probe pads 514 associated with a detection rail 522 (e.g., probe pads 7-9) and/or a trio of probe pads associated with a detection rail 524 (e.g., probe pads 16-18). For example, the tester may ground the probe tip 512 expected to be on probe pad 4 and apply a voltage to the probe tip 412 expected to be on probe pad 5 or probe pad 6. If a current is detected, it may indicate that the probe tips 512 are misaligned and are offset from the bottom of the probe pads 514 as shown in the example in FIG. 5 because the probe tips 512 have created contacts 520 with the detection rail 524. The test may be repeated (or performed simultaneously) for the other trios associated with detection rails 524.

Similarly, the tester may ground the probe tip 512 expected to be on probe pad 1 and apply a voltage to the probe tip 512 expected to be on probe pad 2 or probe pad 3. If a current is detected, it may indicate that the probe tips 512 are misaligned and are off the top of the probe pads 514 (not shown in FIG. 5) because the probe tips 512 have created contacts 520 with the detection rail 522. The test may be repeated (or performed simultaneously) for the other trios associated with detection rails 522. Thus, if the tester detects current through detection rails 522, it can determine the probe tips 512 should be moved down to improve alignment (or the test module 504 should be moved up), and if the tester detects current through detection rails 524, it can determine the probe tips 512 should be moved up to improve alignment (or the test module 504 should be moved down).

Trios of probe tips 512 associated with probe pads 514 may be tested sequentially and in some cases, some trios may be tested simultaneously. The TEG 416 may be utilized to determine if some of the probe tips 512 are missing, failing, and/or not in contact with the probe pad 504. For example, the probe tip 512 associated with probe pad 3 may be grounded and a probe tip 512 associated with probe pad 4 may have a voltage applied. If a current is detected, it means both probe tips 512 are in contact with the probe pads 514. However, if no current is detected, it means that one (or both) of the two probe tips 512 are in contact with the probe pads 514.

Because the detection rails 522 and 524 of the misalignment detector group three probe pads 514, the misalignment detector may be compatible with both single sided and double sided probe cards. The tester may use two probe tips 512 on a same side of the double sided probe card to detect misalignment. The two probe tips 512 are included in a trio of probe tips 512 associated with probe pads 514 of a detection rail 522 or 524. One of the two probe tips 512 may be grounded while a voltage is applied to the other probe tip 512. If a current is detected along the detection rail 522 or 524, the probe tips 512 may be misaligned. As discussed previously, the tests may be repeated (or performed simultaneously) on the remaining trios of probe tips 512. Note that if there is a non-multiple of three number of probe tips 512, one or two probe tips 512 may not be used for detecting misalignment.

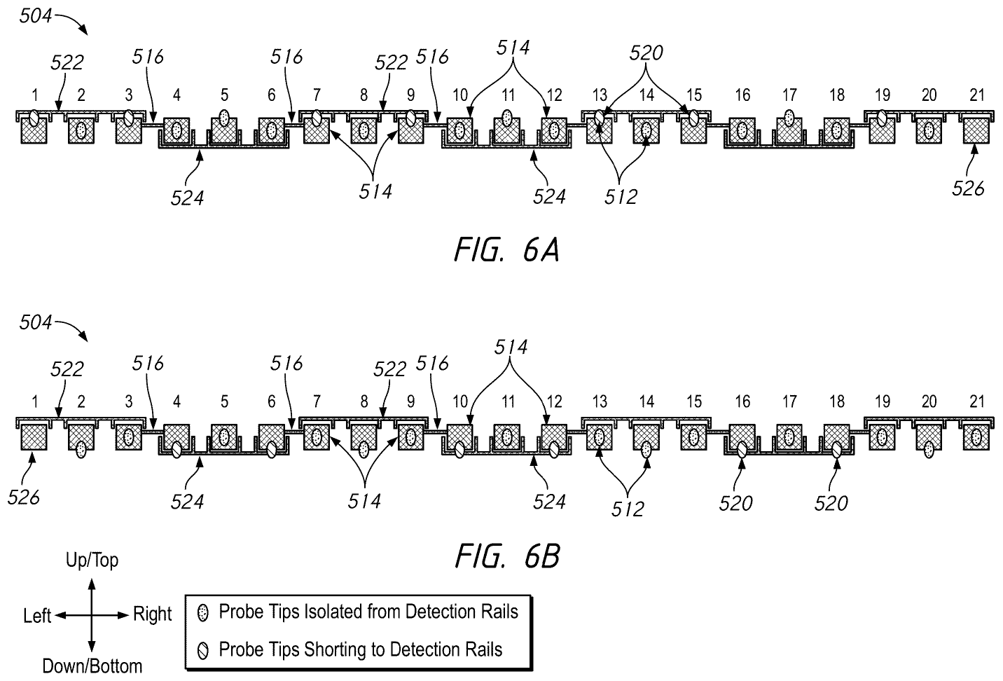

In the example shown in FIG. 6A, the tester may ground a probe tip 512 expected to be placed on probe pad 12 and apply a voltage to a probe tip 512 expected to be on probe pad 15. A current may be detected because the probe tips 512 made contacts 520 with a detection rail 522. Similar tests may be performed on probe tips 512 associated with probe pads 1 and 3, and probe pads 7 and 9. The detection of the current in detection rails 522 may indicate the probe tips 512 may need to be shifted down and/or the test module 504 may need to be shifted up.

In the example shown in FIG. 6B, the tester may ground a probe tip 512 expected to be placed on probe pad 16 and apply a voltage to a probe tip 512 expected to be on probe pad 18. A current may be detected because the probe tips 512 made contacts 520 with a detection rail 524. Similar tests may be performed on probe tips 512 associated with probe pads 4 and 6, probe pads 10 and 12, and probe pads 19 and 21. The detection of the current in detection rails 524 may indicate the probe tips 512 may need to be shifted up and/or the test module 504 may need to be shifted down.

Note that in FIG. 6A, the double-sided card is in a configuration where the probe tips 512 are associated with probe pads 1-20, and in FIG. 6B, the double-sided card is in a configuration where the probe tips 512 are associated with probe pads 2-21. In the configuration shown in FIG. 6A, probe pad 21 may be the additional pad 526, and in the configuration shown in FIG. 6B, probe pad 1 may be the additional pad 526.

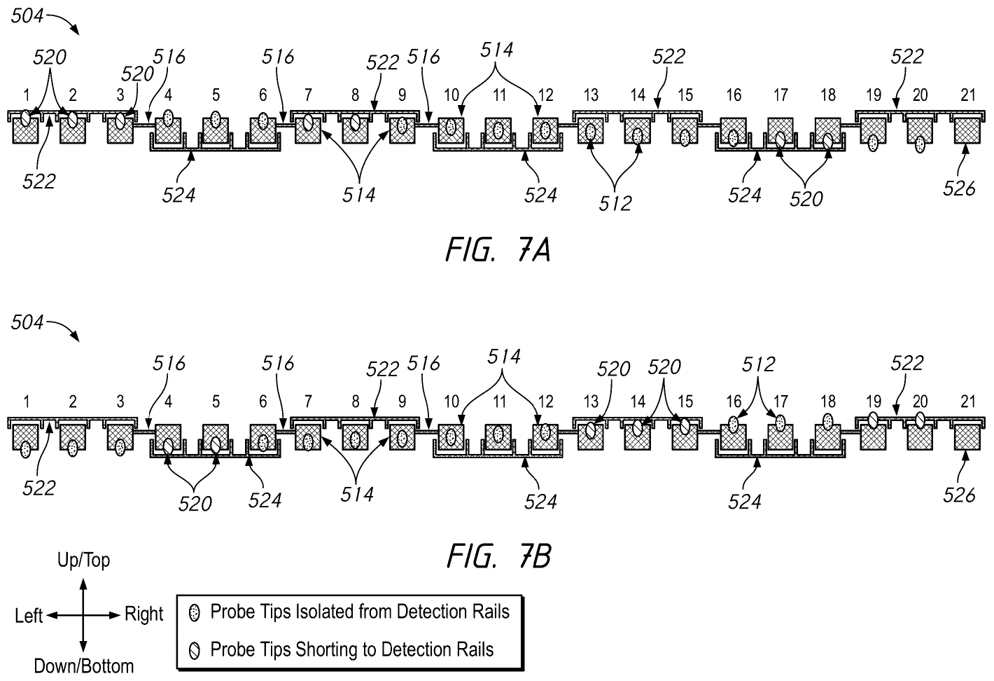

The misalignment detector may be able to detect when the probe card is rotated from the proper alignment with the probe pads 514. As shown in FIG. 7A, the tester may detect a current on the detection rail 522 associated with probe pads 1-3 and a current on detection rail 524 associated with probe pads 16-18. This may allow the tester to determine the probe tips 512 are misaligned in a clockwise direction relative to the test module 504. As shown in FIG. 7B, the tester may detect a current on the detection rail 524 associated with probe pads 4-6 and a current on detection rail 522 associated with probe pads 19-21. This may allow the tester to determine the probe tips 512 are misaligned in a counterclockwise direction relative to the test module 504. In general, when a current is detected on an upper detection rail 522 to the left and a lower detection rail 524 to the right of the test module 504, the probe tips 512 are misaligned in a clockwise direction, and counterclockwise when a current is detected on an upper detection rail to the right and a lower detection rail 524 to the left of the test module 504.

Returning to FIG. 5, the detection rails 522 may include extended portions 523 that extend along at least a portion of the left and right sides of the probe pads 514, and the detection rails 524 may include extended portions 525 that extend along at least apportion of the left and right side of the probe pads 514. If the probe tips 512 are misaligned to the left or right of the probe pads 514, the probe tips 512 may form contacts (not shown) with the extended portions 523 and/or extend portions 525. However, while the tester may be able to determine the probe tips 512 are misaligned to a side, the tester may not be able to determine specifically that the probe tips 512 are misaligned to the left or right.

While the embodiments illustrated in FIGS. 3B-7B may not require a significant amount of additional conductive traces, these embodiments have limited capabilities for detecting open test modules (e.g., when a probe tip is missing, failing, and/or not in contact with a probe pad). In some applications, detecting open test modules may be desirable. If a test module is open, it may indicate that the probe card (e.g., probe card 106) is damaged.

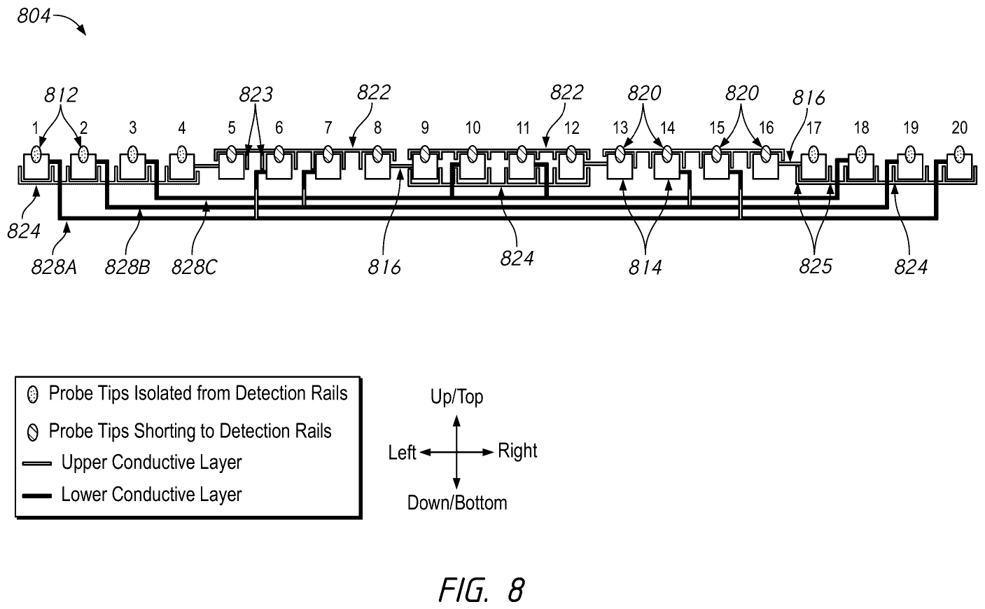

FIG. 8 illustrates a probe tip misalignment detector in accordance with at least one embodiment of the present disclosure. Test module 804 includes a number of probe pads 814. Some of the probe pads 814 (e.g., probe pads 4 and 5 and probe pads 16 and 17) are connected as test element groups 816. The test module 804 further includes detection rails 822 and 824 and shorting lines 828A, 828B, and 828C to act as a misalignment detector. Detection rails 822 and 824 are included in an upper conductive layer along with probe pads 814. The shorting lines 828A, 828B, and 828C are primarily located in a lower conductive layer, but coupled to the upper conductive layer. From the perspective of the reader, the conductive layers are in a plane parallel to the page. The upper conductive layer is closer to the reader and the lower conductive layer is farther from the reader (e.g., into the page).

Detection rails 822 extend along the “top” of sets of four consecutive probe pads 814. Similarly, detection rails 824 extend along the “bottom” of alternating sets of four consecutive probe pads 814. One set of probe pads 814 is associated with both an upper detection rail 822 and a lower detection rail 824. In the example shown in FIG. 8, probe pads 5-8, 9-12, and 13-16 have detection rails 822 along the top, and probe pads 1-4, 9-12, and 17-20 have detection rails 824 along the bottom. However, other arrangements may be used without departing from the scope of the present embodiment (e.g., probe pads 1-4 and 17-20 have detection rails 822 along the top and probe pads 5-8 and 13-16 have detection rails 824 along the bottom).

The shorting lines 828A-C may couple sets of four probe pads 814 together. The groups of probe pads 814 coupled by the shorting lines 828A-C may be probe pads 814 that are not included in a TEG 816. In the example shown in FIG. 8, shorting line 828A couples probe pads 1, 6, 15, and 20 together. Shorting line 828B couples probe pads 2, 7, 14, and 19. Shorting line 828C couples probe pads 3, 10, 11, and 18. Probe pads 4, 5, 8, 9, 16, and 17 are not coupled by the shorting lines 828A-C because in the example shown, these probe pads are coupled by TEG 816. Other configurations of probe pads 814 coupled by the shorting lines 828A-C may be used in other examples.

The detection rails 822 and 824 may allow for a tester to determine whether probe tips 812 are misaligned in the upper or lower directions and/or in the clockwise or counterclockwise rotational directions using techniques similar to those described with reference to the misalignment detector shown in FIGS. 5-7B. Further, the misalignment detector shown in FIG. 8 may be compatible with both one-sided and double-sided cards.

The tester may ground and apply voltages to probe tips 812 associated with a set of probe pads 814 associated with a same detection rail. For example, a set of probe pads 814 associated with a detection rail 822 (e.g., probe pads 5-8) and/or a set of probe pads associated with a detection rail 824 (e.g., probe pads 17-20). For example, the tester may ground the probe tip 812 expected to be on probe pad 4 and apply a voltage to the probe tip 812 expected to be on probe pad 1, 2, or 3. If a current is detected, it may indicate that the probe tips 812 are misaligned and are offset from the bottom of the probe pads 814 (not shown) because the probe tips 812 have created contacts with the detection rail 824. The test may be repeated (or performed simultaneously) for the other sets associated with detection rails 824.

Similarly, the tester may ground the probe tip 812 expected to be on probe pad 8 and apply a voltage to the probe tip 812 expected to be on probe pad 5, 6, or 7. If a current is detected, it may indicate that the probe tips 812 are misaligned and are off the top of the probe pads 814 (not shown) because the probe tips 812 have created contacts with the detection rail 822. The test may be repeated (or performed simultaneously) for the other sets associated with detection rails 822. Thus, if the tester detects current through detection rails 822, it can determine the probe tips 812 should be moved down to improve alignment (or the test module 804 should be moved up), and if the tester detects current through detection rails 824, it can determine the probe tips 812 should be moved up to improve alignment (or the test module 804 should be moved down).

Sets of probe tips 812 associated with probe pads 814 may be tested sequentially and in some cases, some pairs may be tested simultaneously.

The tester may detect a current on the detection rail 824 associated with probe pads 1-4 and a current on detection rail 822 associated with probe pads 13-16. This may allow the tester to determine the probe tips 812 are misaligned in a counterclockwise direction relative to the test module 804 (not shown). The tester may detect a current on the detection rail 824 associated with probe pads 17-20 and a current on detection rail 822 associated with probe pads 5-8. This may allow the tester to determine the probe tips 812 are misaligned in a clockwise direction relative to the test module 804. In general, when a current is detected on an upper detection rail 822 to the left and a lower detection rail 824 to the right of the test module 804, the probe tips 812 are misaligned in a clockwise direction, and counterclockwise when a current is detected on an upper detection rail to the right and a lower detection rail 824 to the left of the test module 804.

The detection rails 822 may include extended portions 823 that extend along at least a portion of the left and right sides of the probe pads 814, and the detection rails 824 may include extended portions 825 that extend along at least apportion of the left and right side of the probe pads 814. If the probe tips 812 are misaligned to the left or right of the probe pads 814, the probe tips 812 may form contacts (not shown) with the extended portions 823 and/or extend portions 825. However, while the tester may be able to determine the probe tips 812 are misaligned to a side, the tester may not be able to determine specifically that the probe tips 812 are misaligned to the left or right.

The shorting lines 828A-C and/or TEG 816 may allow the misalignment detector to detect open pads (e.g., a probe tip 812 is missing, failing, and/or not in contact with a probe pad 814). In the previous embodiments, only probe pads associated with TEG could be tested to determine if a probe tip was missing. However, additional open pads can be detected by the misalignment detector shown in FIG. 8.

To detect open pads, a tester may apply a voltage to a probe tip 812 associated with one probe pad 814 coupled to one of the shorting lines 828A-C, ground another probe tip 812 associated with another probe pad 814 coupled to one of the shorting lines 828A-C, and floating the remaining probe tips 812 associated with the remaining probe pads 814 coupled to the respective shorting line 828A-C. These tests can be repeated for the various combinations of probe tips 812 associated with the shorting lines 828A-C If currents are detected, it indicates that all probe tips 812 associated with the shorting line 828A-C are in contact with the respective probe pads 814. If a current is not detected in one of the tests, it indicates that one of the pads 814 is open.

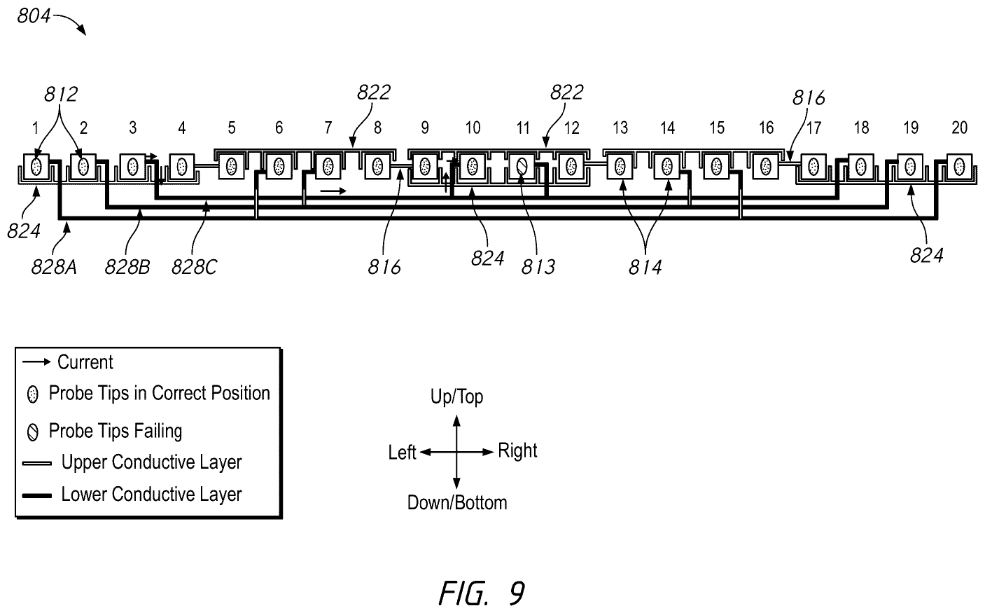

FIG. 9 illustrates an example where probe pad 11 is associated with a missing/failing/no contact probe tip 813. In the example, in a first test, the tester checks for a current between probe pad 3 and probe pad 10 along shorting line 828C. A voltage is applied to probe pad 3, and a current (indicated by the small arrows along shorting line 828C) flows to probe pad 10, which may be grounded by a probe tip 812. This indicates that both probe tips 812 on probe pad 3 and probe pad 10 are in contact with the probe pads 814. However, when probe pad 11 is expected to be grounded, no current is detected. Because a current was detected between probe pads 3 and 10, it is known that the probe tips 812 are in contact with those pads. Accordingly, the tester can determine probe pad 11 is open, and probe tip 813 is missing, not in contact with probe pad 11, and/or malfunctioning.

Various combinations of tests may be performed to determine which (if any) probe pad 814 is open. For example, if no currents were detected between probe pad 3 and probe pads 10 and 11, the tester could apply a voltage to probe pad 10 and ground probe pad 18 and then apply a voltage to probe pad 3 and ground probe pad 18 to help determine if probe pad 3 is open or if both probe pads 10 and 11 are open.

The misalignment detectors shown in FIGS. 3B-9 may detect when probe tips are shifted to a side (e.g., left/right) of the probe pads due to the portions of the detection rails that extend on either side of the probe pads. However, the electrical signals received from the tester will be the same regardless of whether the probe tips are shifted to the left or shifted to the right. Thus, the tester (or a user of the tester) must use trial and error to determine whether the probe pins (or test module) need to be shifted to the left or right to improve the alignment.

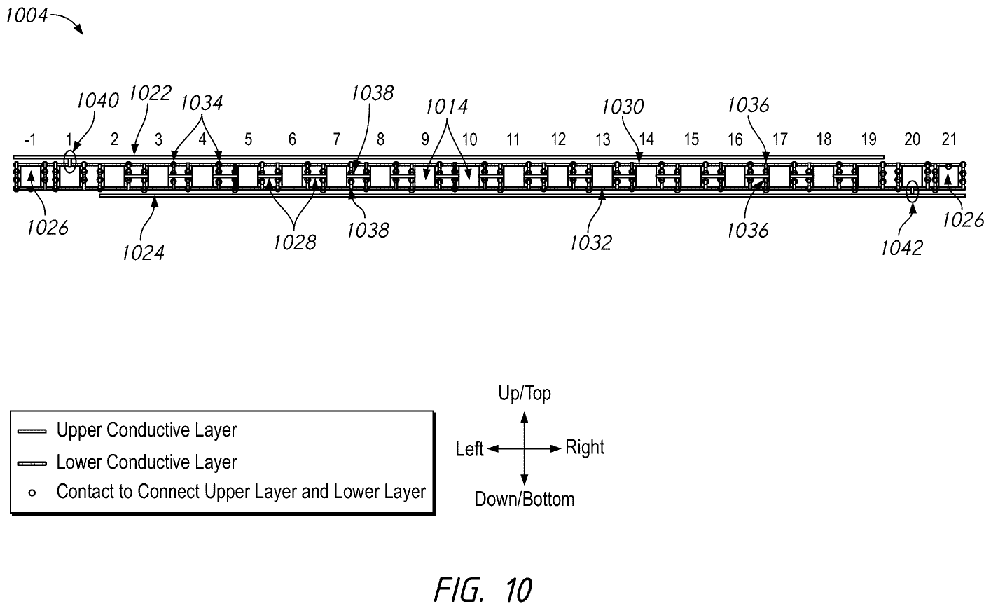

FIG. 10 illustrates a probe tip misalignment detector in accordance with at least one embodiment of the present disclosure. Test module 1004 includes a number of probe pads 1014. The test module 1004 may include two additional probe pads 1026, one on each end. In the example shown in FIG. 10, the additional pads 1026 include probe pads −1 and 21. The test module 1004 includes a detection rail 1022 extending across the tops of probe pads −1-19 and detection rail 1024 extending along the bottoms of probe pads 2-21 in an upper conductive layer. Probe pad 1 may be coupled to the detection rail 1022 by conductive trace 1040, and probe pad 20 may be coupled to the detection rail 1024 by conductive trace 1042. To the left of the probe pads 1014, are left detection rails 1036, and to the right of the probe pads 1014 are right detection rails 1038 in the upper conductive layer. Shorting lines 1028 couple probe pads 2-19 in the upper conductive layer. A conductive trace 1030 extends along the tops of probe pads −1-21 in a lower conductive layer, and a conductive trace 1032 extends along the bottom of probe pads −1-21 in the lower conductive layer. From the perspective of the reader, the conductive layers are in a plane parallel to the page. The upper conductive layer is closer to the reader and the lower conductive layer is farther from the reader (e.g., into the page).

Various elements in the upper and lower conductive layers may be connected via contacts 1034 that extend between the upper and lower conductive layers. Probe pad −1 may be coupled via a contact 1034 to the bottom conductive trace 1032. Probe pad 21 may be coupled via a contact 1034 to the top conductive trace 1030. Further, the left detection rails 1036 may be coupled to the conductive trace 1032 via contacts 1034 to be electrically coupled to the probe pad −1. The right detection rails 1038 may be coupled via contacts 1034 to the conductive trace 1030 to be electrically coupled to probe pad 21.

The misalignment detector may include the detection rails 1022, 1024, 1036, and 1038, additional pads 1026, and conductive traces 1030, 1032, 1040, and 1042. The misalignment detector may be compatible with both single-sided and double-sided probe cards.

The detection rail 1022 may be used to determine whether the probe tips (not shown in FIG. 10) are shifted upwards relative to the probe pads 1014. The tester may apply a voltage to a probe tip associated with probe pad 1 and ground one of probe tips associated with probe pads 2-19 (or vice versa). The remaining probe tips may be floated. If a current is detected between the two probe tips, it indicates that the probe tips are shifted upwards because probe pad 1 is not connected to shorting line 1028, and detection rail 1024 is not below probe pad 1. Accordingly, the probe tip associated with probe pad 1 is coupled to probe tips associated with probe pads 2-19 due to contacts formed between the probe tips and the detection rail 1022. Thus, the probe tips may be shifted downward (and/or the test module 1004 shifted upwards) to improve alignment between the probe pads 1014 and the probe tips.

The detection rail 1024 may be used to determine whether the probe tips are shifted downwards relative to the probe pads 1014. The tester may apply a voltage to a probe tip associated with probe pad 20 and ground one of the probe tips associated with probe pads 2-19 (or vice versa). The remaining probe tips may be floated. If a current is detected between the two probe tips, it indicates that the probe tips are shifted downwards because probe pad 20 is not connected to shorting line 1028, and detection rail 1022 is not above probe pad 20. Accordingly, the probe tip associated with probe pad 20 is coupled to probe tips associated with probe pads 2-19 due to contacts formed between the probe tips and the detection rail 1022. Thus, the probe tips may be shifted upward (and/or the test module 1004 shifted downward) to improve alignment between the probe pads 1014 and the probe tips.

The additional pads 1026 may be used to detect whether the probe tips are shifted to the left or right relative to the probe pads 1014. Specifically, the coupling of the additional pads 1026 to the left and right detection rails 1036, 1038 via the conductive traces 1030, 1032 may allow for a tester to apply a voltage between a probe tip associated with one of the additional probe pads 1026 and a probe tip associated with another probe pad 1014. If a current is detected associated with one of the additional pads 1026, the probe tips are misaligned to the left or right.

When probe tips are misaligned such that they slip to the left of the probe pads 1014, the probe tips may form contacts with one or more of the left detection rails 1036. The left detection rails 1036 are coupled to probe pad −1 via connections to conductive trace 1032. When a tester measures a current at probe pad −1, it indicates the probe tips are shifted to the left. When probe tips are misaligned such that they slip to the right of the probe pads 1014, the probe tips may form contacts with one or more of the right detection rails 1038. The right detection rails 1038 are coupled to probe pad 21 via connections to the conductive trace 1032. When a tester measures a current at probe pad 21 it indicates the probe tips are shifted to the right.

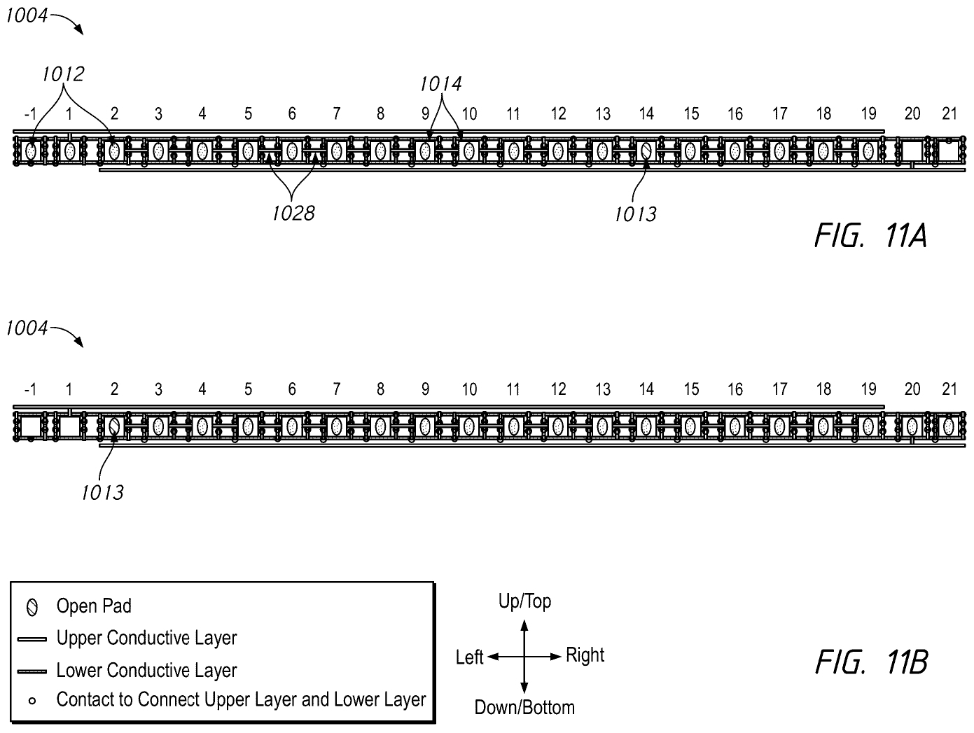

The misalignment detector of test module 1004 may also detect probe tips that are missing or malfunctioning. As shown in FIG. 11A, the probe tips 1012 may be placed on the probe pads 1014 such that the probe tips 1012 are expected to make contact with probe pads −1 through 19. This may allow the tester to find missing or malfunctioning probe tips associated with probe pads 2 through 19. The tester may apply a voltage to a probe tip 1012 associated with a probe pad 1014 and ground a probe tip 1012 associated with another probe pad 1014 and measure a current between the probe pads 1014. The remaining probe tips 1012 may be floated by the tester. If both probe tips 1012 are in contact with the probe pads 1014, a current will flow through the shorting line 1028. If one of the probe tips 1012 is missing (e.g., not in contact with the probe pad 1014) or malfunctioning, no current will be detected. The tester may apply a voltage to each probe tip 1012, one at a time, while measuring a current at an adjacent probe tip 1012 that has been grounded to identify open probe pads. However, other testing patterns could be used. For example, the tester may apply a voltage to a probe tip 1012 associated with probe pad 2 and ground a probe tip 1012 associated with probe pad 19.

In the example shown in FIG. 11A, the tester may measure a current between probe pads 12 and 13. A current is detected because both probe pads 12 and 13 are in contact with corresponding probe tips 1012. The tester may measure a current between probe pad 13 and 14. No current is detected because a missing/failing/no contact probe tip 1013 is associated with probe pad 14 (e.g. probe pad 14 is open). Because a current was detected when the tester was measuring a current at probe pad 13, it can be determined that probe pad 14 is the one associated with the probe tip 1013.

As shown in FIG. 11B, the probe tips 1012 may be placed on the probe pads 1014 such that the probe tips 1012 are expected to make contact with probe pads 2 through 21. This may allow the tester to find missing or malfunctioning probe tips associated with probe pads 2 through 21. Thus, the probe tips 1012 that has been in contact with probe pads −1 and 1 in FIG. 11A that were not tested can now be tested in a similar manner as described with reference to FIG. 11A.

In the example shown in FIG. 11B, the tester may measure a current between probe pads 2 and 3. A current is not detected because probe pad 2 is associated with a missing/failing/no contact probe tip 1013. The tester may measure a current between probe pad 3 and 4. Because probe pads 3 and 4 are in contact with functioning probe tips 1012, a current is detected. Because a current was detected when the tester was measuring a current at probe pad 3 during the measurement with probe pad 4, it can be determined that probe pad 2 is the one associated with the probe tip 1013, not probe pad 3.

As noted above, the misalignment detector can determine if the probe tips 1012 are misaligned upwards or downwards relative to the probe pads 1014. The misalignment detector can further determine if only certain probe tips 1012 between probe pads 2-19 are misaligned (e.g., one of the probe tips 1012 is bent).

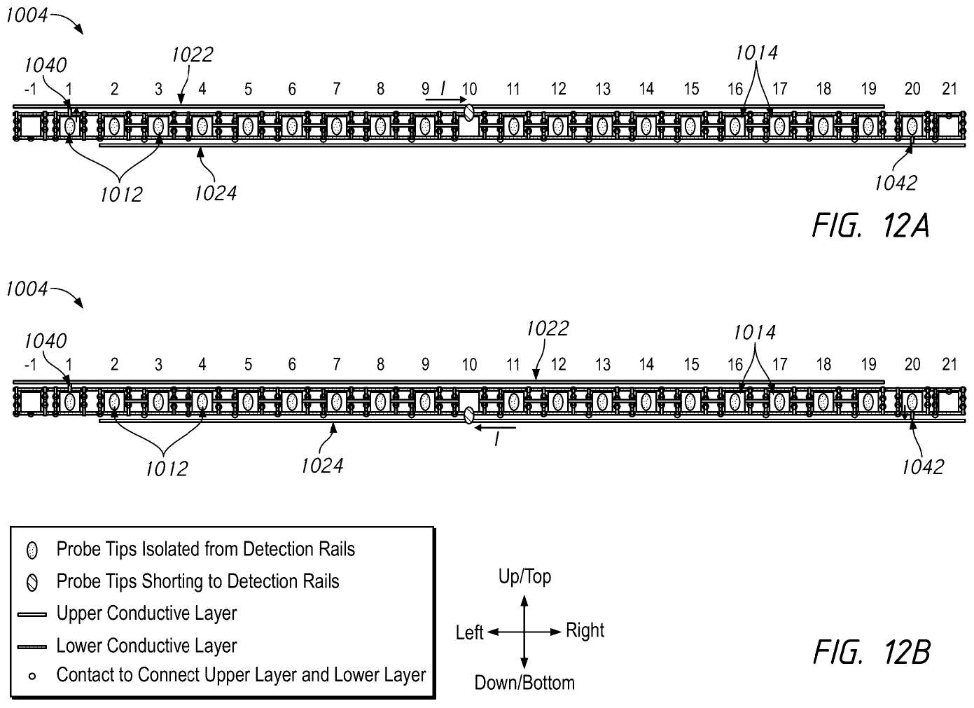

FIG. 12A shows an example when a probe tip 1012 is misaligned to the top of probe pad 10. The tester can apply a voltage (or ground) a probe tip 1012 associated with probe pad 1 and ground (or apply a voltage) to the probe tip 1012 associated with one of probe pads 2-19 and measure a current. If any of the probe tips 1012 associated with probe pads 2-19 are shifted upwards, a current will be detected because probe pad 1 is coupled to the detection rail 1022 by conductive trace 1040. In the example shown, when the tester measures a current between probe pad 1 and a probe tip associated with probe pad 10, a current is detected as indicated by the arrow labeled with “I.” Accordingly, the tester can determine that the probe tip 1012 expected to be in contact with probe pad 10 is shifted upwards relative to the probe pad 10. This may allow a user to determine that the probe pin should be adjusted (e.g., bent back to its proper position) or the probe card should be replaced.

FIG. 12B shows an example when a probe tip 1012 is misaligned to the bottom of probe pad 10. The tester can apply a voltage (or ground) a probe tip 1012 associated with probe pad 20 and ground (or apply a voltage) to the probe tip 1012 associated with one of probe pads 2-19 and measure a current. If any of the probe tips 1012 associated with probe pads 2-19 are shifted downwards, a current will be detected because probe pad 20 is coupled to the detection rail 1024 by conductive trace 1042. In the example shown, when the tester measures a current between probe pad 20 and a probe tip associated with probe pad 10, a current is detected as indicated by the arrow labeled with “I.” Accordingly, the tester can determine that the probe tip 1012 expected to be in contact with probe pad 10 is shifted downwards relative to the probe pad 10. This may allow a user to determine that the probe pin should be adjusted (e.g., bent back to its proper position) or the probe card should be replaced.

The detections rails 1022 and 1024 may be used to determine whether the probe tips are rotationally misaligned from the probe pads 1014. As shown in FIG. 10, the detection rail 1022 does not extend across probe pads 20 and 21, and detection rail 1024 does not extend across probe pads −1 and 1. If a current is detected by a probe tip associated with probe pad 1 along detection rail 1022, and a current is detected by a probe tip associated with probe pad 20 along detection rail 1024, it may indicate the probe tips are misaligned in a clockwise direction. If a current is detected by a probe tip associated with probe pad 19 and another probe tip along detection rail 1022, but no current is detected associated with a probe tip associated with probe pad 1, and a current is detected by a probe tip associated with probe pad 2 and another probe tip along detection rail 1024, but no current is detected associated with a probe tip associated with probe pad 20, it may indicate the probe tips are misaligned in a counterclockwise direction.

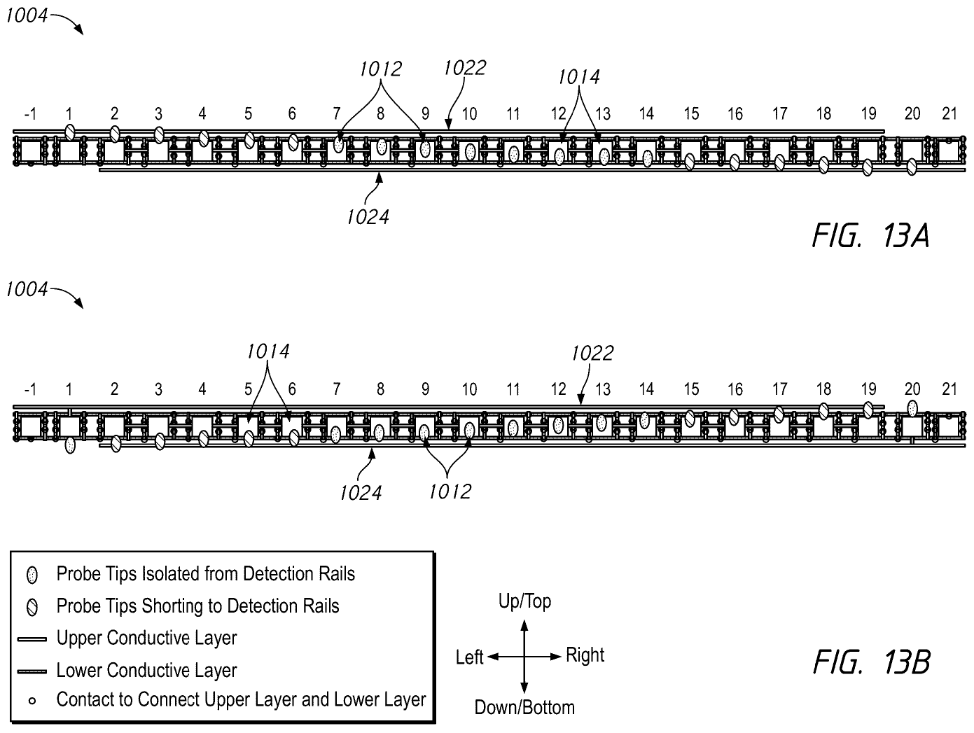

FIG. 13A shows an example when the probe tips 1012 are rotationally misaligned from the probe pads 1014 in a clockwise direction. In one example, the tester may measure a current between a probe tip associated with probe pad 1 and probe pad 2 as well as measure a current between the probe tip associated with probe pad 1 and probe pad 19. If a current detected for both tests due to detection rail 1022, the probe tips are shifted upwards. However, if no current is detected between probe tips associated with probe pad 1 and probe pad 19 when a current is detected between the probe tips associated with probe pads 1 and 2, it may indicate that the probe tips are misaligned in a clockwise direction. The tester may test for a current between probe tips associated with probe pads 19 and 20. If a current is detected due to detection rail 1024, it may confirm the rotational misalignment. This is provided merely as an example, and the tester may measure currents between additional or different combinations of probe tips (e.g., probe tips associated with probe pad 1 and probe pad 3).

FIG. 13B shows an example when the probe tips 1012 are rotationally misaligned from the probe pads 1014 in a counterclockwise direction. In one example, the tester may measure a current between probe tips associated with probe pads 1 and probe pad 2 as well as measure a current between probe tip associated with probe pad 19 and 20. If no current is detected between either pair of probe tips, this may indicate that the probe tips are misaligned in a counterclockwise manner as it indicates the probe tips associated with probe pad 1 and 20 have lost contact with the probe pads and are not in contact with detection rail 1022 or 1024. The tester may further measure a current between probe tips associated with probe pads 2 and 3 and measure a current between probe tips associated with probe pads 18 and 19. If currents are detected, it may confirm that probe tips associated with probe pads 2, 3, 18, and 19 are functioning properly. However, this step may be omitted if probe tips were previously tested as described with reference to FIGS. 11A and 11B.

While the misalignment detector shown in FIGS. 10-13B may require more additional conductive lines compared to the misalignment detectors shown in FIGS. 3B-9, the misalignment detector may allow a tester to determine additional types of misalignment and/or with greater granularity. In some applications where determining what corrective actions need to be taken to improve alignment is difficult (e.g., where the size of the probe pins and/or probe pads are small and/or the number of probe pins and pads is very high), the cost and/or space disadvantages of the misalignment detector shown in FIGS. 10-13B may be outweighed by the benefits of improved and/or faster alignment of the probe card with the test module.

The present application provides various embodiments for misalignment detectors for determining when one or more probe tips of a probe card are misaligned (e.g., not fully on, not in contact with) from one or more probe pads of a test module on a wafer. The various misalignment detectors may provide varying compatibility with double-sided and single-sided cards and varying ability to provide information on different types of misalignment (e.g., top vs. bottom, left vs. right, identification of missing tips, etc.). Which embodiment of a misalignment detector is preferable may depend, at least in part, on the application. For example, where space and/or simplicity of the test module is higher priority than a tester being able to obtain detailed misalignment information, misalignment detectors such as those shown in FIGS. 3B, 4, and/or 5 may be preferable. Where a tester being able to obtain misalignment information is higher priority than space and/or complexity of the test module, misalignment detectors such as those shown in FIGS. 8 and 10 may be preferable.

From the foregoing it will be appreciated that, although specific embodiments of the disclosure have been described herein for purposes of illustration, various modifications may be made without deviating from the spirit and scope of the disclosure. Accordingly, the disclosure is not limited except as by the appended claims.

What is claimed is:

1. An apparatus comprising:
a plurality of probe pads; and
a misalignment detector comprising:
a first detection rail extending along a first side of at least two of the plurality of probe pads; and
a second detection rail extending along a second side of at least two of the plurality of probe pads, wherein the second side is opposite the first side.

2. The apparatus of claim 1, wherein the at least two of the plurality of probe pads along which the first detection rail extends is the same as the at least two of the plurality of probe pads along which the second detection rail extends.

3. The apparatus of claim 1, wherein the first detection rail comprises first extending portions that extend along third sides of the at least two of the plurality of probe pads and second extending portions that extend along fourth sides of the at least two of the plurality of probe pads, wherein the third sides are opposite the forth sides, and
wherein the second detection rail comprises third extending portions that extend along third sides of the at least two of the plurality of probe pads and fourth extending portions that extend along fourth sides of the at least two of the plurality of probe pads, wherein the third sides are opposite the forth sides.

4. The apparatus of claim 1, wherein the at least two of the plurality of probe pads along which the first detection rail extends is different than the at least two of the plurality of probe pads along which the second detection rail extends,
wherein the first detection rail extends along the first side of first alternating pairs of the plurality of probe pads, wherein the at least two of the plurality of probe pads are included a pair of the first alternating pairs, and
wherein the second detection rail extends along the second side of second alternating pairs of the plurality of probe pads, wherein the at least two of the plurality of probe pads are included a pair of the second alternating pairs.

5. The apparatus of claim 1, wherein the at least two of the plurality of probe pads along which the first detection rail extends is different than the at least two of the plurality of probe pads along which the second detection rail extends,
wherein the first detection rail extends along the first side of first alternating trios of the plurality of probe pads, wherein the at least two of the plurality of probe pads are included a trio of the first alternating trios, and
wherein the second detection rail extends along the second side of second alternating trios of the plurality of probe pads, wherein the at least two of the plurality of probe pads are included a trio of the second alternating trios.

6. The apparatus of claim 5, wherein the misalignment detector further comprises an additional probe pad.

7. The apparatus of claim 5, wherein a number of the plurality of probe pads comprises a multiple of three.

8. The apparatus of claim 1, wherein at least two of the plurality of probe pads are coupled as a test element group.

9. An apparatus comprising:
a plurality of probe pads comprising a plurality of sets of four probe pads; and
a misalignment detector comprising:
a first detection rail extending along a first side of a first set of the plurality of probe pads;
a second detection rail extending along a second side of a second set of the plurality of probe pads, wherein the second side is opposite the first side;
a third detection rail extending along the first side of a third set of the plurality of sets;
a fourth detection rail extending along the second side of the third set of the plurality of sets;
a fifth detection rail extending along the second side of a fourth set of the plurality of sets; and
a sixth detection rail extending along the first side of a fifth set of the plurality of sets.

10. The apparatus of claim 9, further comprising a shorting line coupling at least one probe pad from a set of the plurality of sets to at least one probe pad from a different set of the plurality of sets.

11. The apparatus of claim 10, wherein at least a portion of the shorting line is located in a first conductive layer, and the plurality of probe pads, the first, second, third, fourth, and fifth detection rails are located in a second conductive layer.

12. The apparatus of claim 9, further comprising:
a first shorting line coupled between a first probe pad of the first set, a second probe pad of the second set, a third probe pad of the fourth set, and a fourth probe pad of the fifth set;
a second shorting line coupled between a fifth probe pad of the first set, a sixth probe pad of the second set, a seventh probe pad of the fourth set, and an eighth probe pad of the fifth set; and
a third shorting line coupled between a ninth probe pad of the first set, a tenth probe pad of the third set, an eleventh probe pad of the third set, and a twelfth probe pad of the fifth set.

13. The apparatus of claim 9, wherein a first probe pad and a second probe pad are coupled as a test element group, wherein the first probe pad and the second probe pad are in different sets.

14. An apparatus comprising:
a plurality of probe pads, wherein a first probe pad of the plurality of probe pads is at a first end and a last probe pad of the plurality of probe pads is at a second end opposite the first end; and
a misalignment detector comprising:
a first additional pad at the first end adjacent to the first pad;
a second additional pad at the second end adjacent to the last pad;
a first detection rail extending along a first side of the first additional pad and the plurality of probe pads stopping before the last probe pad;
a second detection rail extending along a second side of the second additional pad and the plurality of probe pads stopping before the first probe pad, wherein the second side is opposite the first side;
a plurality of left detection rails extending along third sides of the plurality of probe pads and the first and second additional pads; and
a plurality of right detection rails extending along fourth sides of the plurality of probe pads and the first and second additional pads.

15. The apparatus of claim 14, further comprising a shorting line coupling the plurality of probe pads from a second probe pad of the plurality of probe pads to a second to last probe pad of the plurality of probe pads.

16. The apparatus of claim 14, wherein the first probe pad is coupled to the first detection rail and the last probe pad is coupled to the second detection rail.

17. The apparatus of claim 14, wherein the first additional pad is coupled to the plurality of left detection rails and the second additional pad is coupled to the plurality of right detection rails.

18. The apparatus of claim 17, further comprising a first conductive trace coupling the plurality of left detection rails to the first additional pad, and a second conductive trace coupling the plurality of right detection rails to the second additional pad, wherein the first and second conductive trace are located in a first conductive layer, and the plurality of left detection rails and the second detection rails are located in a second conductive layer.

19. The apparatus of claim 18, further comprising a plurality of contacts coupling the first conductive layer and the second conductive layer.

20. The apparatus of claim 19, wherein the first additional pad and the second additional pad are located in the second conductive layer, and the first additional pad is coupled to the first conductive trace by a first contact of the plurality of contacts and the second additional pad is coupled to the second conductive trace by a second contact of the plurality of contacts.
